(19) United States
(12) Patent Application Publication
(10) Pub. No.: US 2009/0291510 A1
(43) Pub. Date: Nov. 26, 2009

(54) METHOD FOR CREATING WAFER TEST PATTERN

(75) Inventors: Steven C. Catlett, Poughkeepsie, NY (US); Kevin K. Dezfulian, Mount Kisco, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/123,546

(22) Filed: May 20, 2008

(51) Int. Cl. H01L 21/66

(52) U.S. Cl. 438/11; 438/401; 257/E21.531

(57) ABSTRACT

A method for creating a testing pattern for sampling the sheet resistance of a test wafer for tuning an annealing process includes establishing a center point for the wafer and determining a plurality of sample points having a radial displacement from the center point of the wafer and an angular displacement, the radial displacement of successive sample points decreasing in radial distance from one another as the distance from the center point increases and the angular displacement between each successive sample point being constant.

### BACKGROUND OF THE INVENTION

1. Field of the Invention

The present disclosure relates generally to silicon wafers and, in particular, testing the effects of thermal annealing on a silicon wafer.

2. Description of the Related Art

The diffusion and electrical activation caused by thermal annealing is a critical step in semiconductor manufacturing. In the semiconductor industry, silicon wafers are annealed, so that dopant atoms, usually boron, phosphorus or arsenic, can diffuse into substitutional positions in the crystal lattice, resulting in drastic changes in the electrical properties of the silicon wafer. Variations in the conditions of the thermal anneal(s) directly modulate the current drive and standby power of electrical circuits created on the silicon wafer. Thus, controlling the thermal annealing of a wafer is an important part of the semiconductor fabrication process.

Presently, specific methods are available for monitoring the effects of thermal annealing. These methods include utilizing a monitor substrate or test wafer. The monitor substrate is implanted with the dopant atoms and annealed under the annealing conditions to be monitored. The sheet resistance of the monitor substrate is then measured at a plurality of locations across the surface of the monitor substrate. In some instances, the sheet resistance is measured by a four-point probe. By utilizing these measurements, the spatial thermal output of the annealing process may be tuned to minimize variations in sheet resistance across a monitor substrate.

In more detail, at present, a doped monitor wafer is annealed. The sheet resistance of the monitor wafer is then measured at, for example, 121 points across the wafer. Based on these measurements, the operation of the annealing machine may be adjusted to vary the orientation or intensity of lamps within the annealing machine to, hopefully, reduce variations in the sheet resistance across the monitor substrate. One of ordinary skill in the art will realize that sheet resistance is a convenient way to model the diffusion and activation of dopant particles in a semiconductor wafer.

### BRIEF SUMMARY OF THE INVENTION

One embodiment of the present invention is directed to a method for creating a testing pattern for sampling the sheet resistance of a test wafer for tuning an annealing process. The method of this embodiment includes establishing a center point for the wafer and determining a plurality of sample points having a radial displacement from the center point of the wafer and an angular displacement around the wafer. The radial displacement of successive sample points decreases in radial distance from one another as the distance from the center point increases and the angular displacement between each successive sample point is constant.

Another embodiment of the present invention is directed to a method for testing a test wafer to determine the effectiveness of an annealing process. The method of this embodiment includes receiving a plurality of sheet resistance samples taken from a surface of the test wafer, the samples being taken at successive sample locations on the surface of wafer where a radial displacement of each successive sample location decreases in radial distance from one another as the distance from a center point of the test wafer increases and the angular displacement between each successive sample location is constant; and adjusting the annealing process based on the plurality of sheet resistance samples.

Other systems, methods, and/or computer program products according to embodiments will be or become apparent to one with skill in the art upon review of the following drawings and detailed description. It is intended that all such additional systems, methods, and/or computer program products be included within this description, be within the scope of the present invention, and be protected by the accompanying claims.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 depicts a prior art line scan pattern on a wafer;

FIG. 2 depicts a prior art contour map pattern on a wafer;

FIGS. 3A and 3B depict rotated versions of a line scan pattern on a wafer;

FIGS. 4A and 4B depict test patterns according to embodiments of the present invention;

FIG. 5 depicts a block diagram of a method according to an embodiment of the present invention;

FIG. 6 depicts a detailed block diagram of a method of creating a wafer test pattern according to an embodiment the present invention; and

FIG. 7 depicts a block diagram of a method of tuning an annealing process according to an embodiment of the present invention.

The detailed description explains the preferred embodiments of the invention, together with advantages and features, by way of example with reference to the drawings.

### DETAILED DESCRIPTION

At present, two patterns for testing the annealing process of a wafer dominate wafer testing. The first is a so-called “line scan” and the second is a “contour map.”

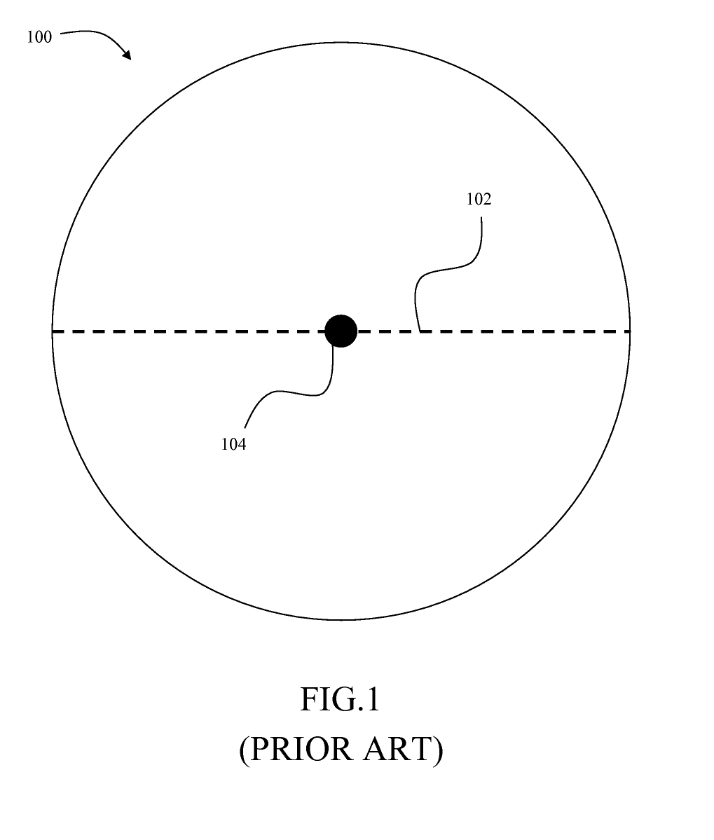

FIG. 1 shows an example of a test wafer 100 and a potential line scan pattern 102 overlaying it. The line scan pattern 102, in this example, may be composed of 121 sample points that pass through the center 104 of the test wafer 100. This allows for sampling at 61 unique radii if the center point is considered a radius of zero. The line scan pattern 102 may be sufficient to determine the consistency of the annealing process in one direction (radial) for the test wafer 100. The line scan pattern 102 may not, however, determine variations in the sheet resistance in all four quadrants of the test wafer 100. As one of ordinary skill in the art will realize, variations could exist in all four quadrants. If the wafer is not centered on the rotational element during annealing, variations of the sheet resistance may exist in one or more of the quadrants.

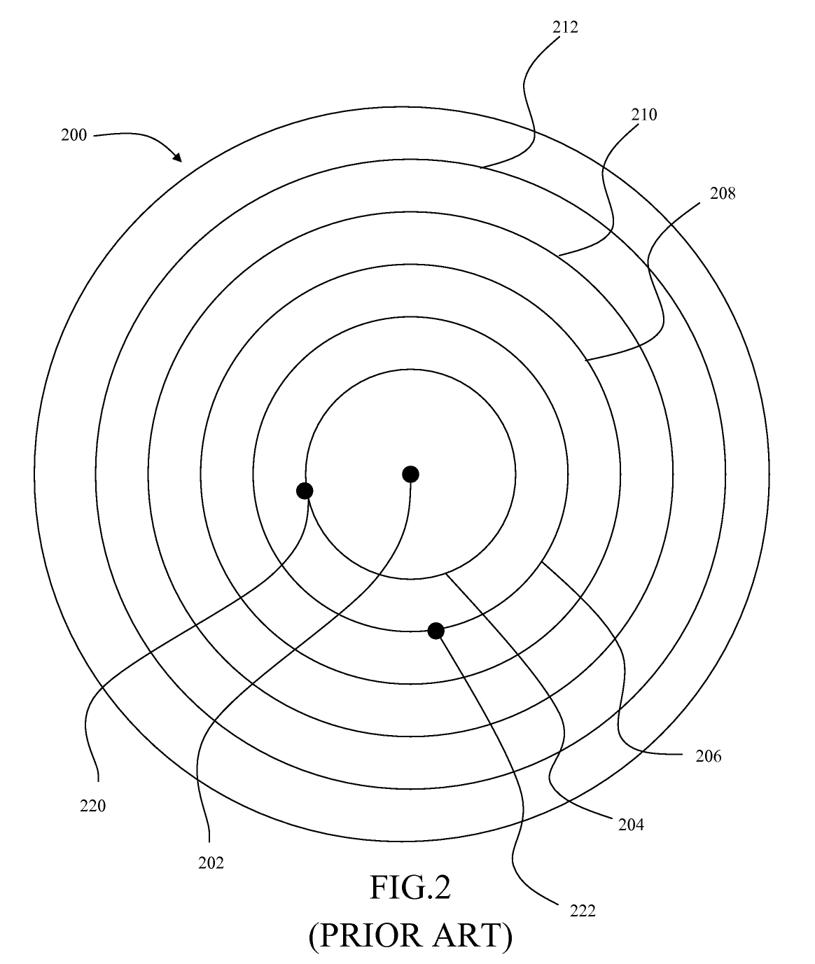

FIG. 2 shows another test wafer 200 having a contour map pattern shown thereon. The contour map pattern is a known way to determine if a test wafer has variations across all four of its quadrants. The contour map includes a center point 202 and 5 concentric circles, 204, 206, 208, 210 and 212. Each circle may include a plurality of sample points located along the circumference of the circle. Examples of such sample points are illustrated at sample point 220 on the first circle 204 and sample point 222 on the second circle 206. Utilizing a test pattern that has such a topology is limited in that it allows for sampling only at 6 unique radii. Limiting the sampling to these unique radii may allow, for example, wide variations in sheet resistance in locations between the concentric circles.

It will be understood by one of skill in the art that a test portion of an annealing machine may follow any pattern. That is, any configuration of test points may be utilized by the machine to test the wafer. As such, the pattern of points that are tested may not be limited to the two described above. For instance, a pattern may be used that represents a line scan placed on a wafer that is rotated. Such a pattern may, in some instance, be more effective in determining if variations exist in each of the quadrants of a circular wafer.

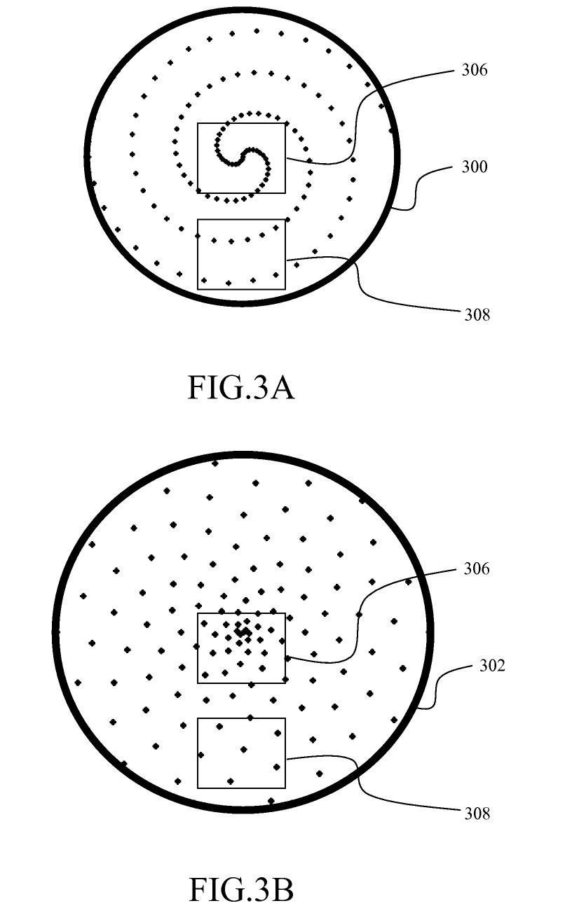

FIG. 3A shows an example of a pattern that may be created if a line scan is applied to a rotated wafer 300. In this example, the wafer 300 is rotated through 7(π/2) radians as the 161 points are sampled. Of course, the pattern could be created by moving the probe to each point and not rotating the wafer.

FIG. 3b shows an example of another pattern that may be created is a line scan is applied to another wafer 302. In this example, the wafer 302 has been rotated through 35(π/2) radians. In both FIG. 3A and FIG. 3b two boxes 306 and 308 of identical area are shown overlaying the sample pattern. In both cases, the number of points in box 306 exceeds the number in the box 308. This reveals a possible shortcoming of a rotated line scan testing pattern. Namely, the wafer is sampled more in the center than near the edge. In other terms, the center of the wafer is oversampled and the edge of the wafer is undersampled. Thus, while a rotated line scan pattern may allow for testing in all four quadrants, there may exist a need for a more uniform sampling pattern.

One possible approach is to generate a pattern that has sample points that are arranged such that the radial density of the points increases quadratically from the center of the wafer to the edge of the wafer. Further, the points may also be arranged such that the angular distance between sequential points is constant. That is, the density of angular displacements may be constant around the wafer. It should be noted that the angular distance between points may be constant in the patterns shown in FIGS. 3A and 3b.

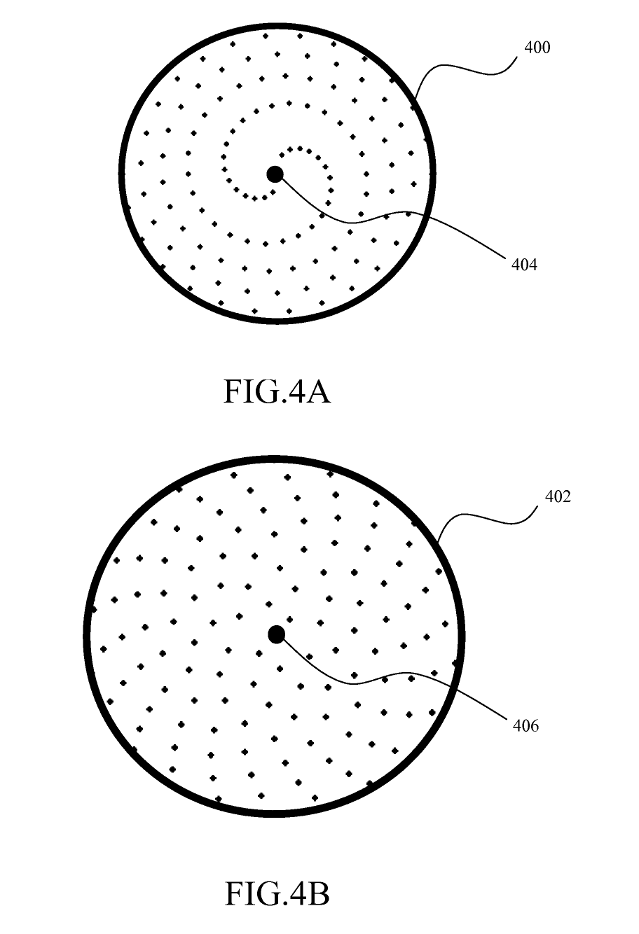

FIG. 4A shows a test pattern on another wafer 400 that varies quadratically in radial density and has a constant angular distance between the sequential points. FIG. 4A shows the wafer rotated through 7(π/2) radians. Each point shown on FIG. 4A has a distance r from the center point 404 and an angular displacement.

FIG. 4B shows a test pattern on another wafer 402 that varies quadratically in radial density and has a constant angular distance between the sequential points. FIG. 4B shows the wafer rotated through 33(π/2) radians. Each point shown on FIG. 4B has a distance r from the center point 406 and an angular displacement.

In one embodiment, a test pattern may be created that the radial density of the points increases quadratically from the center of the wafer to the edge of the wafer and the angular distance between sequential points is constant. The location of points for sample may be sequentially determined by solving two separate equations, one for the radial displacement 1, (Eq. (1)) and one for the angular displacement θ (Eq. (2)).

r=R(|n|/N)^{1/2} Eq. (1):

where R is the maximum radius of a useable portion of the wafer, and there are 2N+1 samples on the domain n=−N . . . 0 . . . N. In some embodiments, N may be equal to 60 yielding 121 sample points.

θ=π−nk/N for n<0 and θ=nk/N for n≧0 Eq. (2):

where k is the angular distance between each point. In some embodiments, k may be equal to 33(π/2).

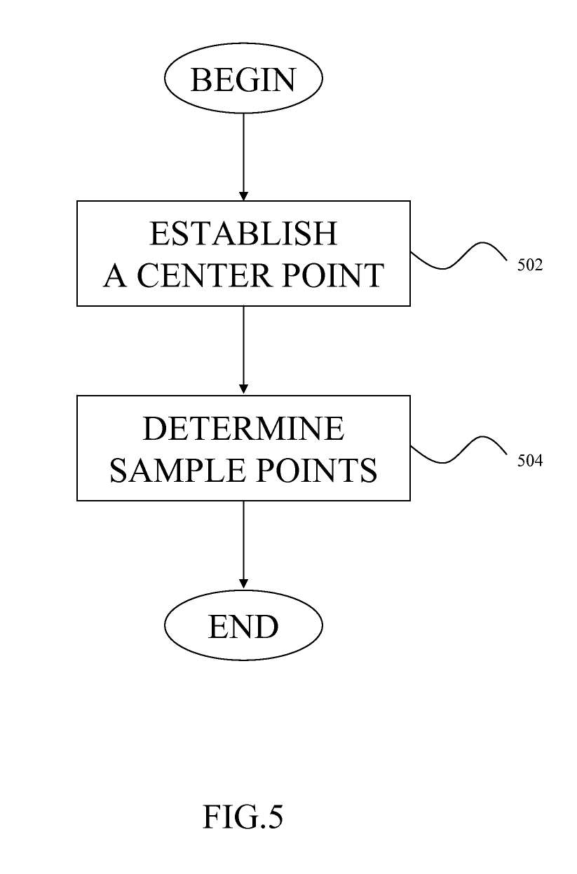

FIG. 5 shows one method according to an embodiment of the present invention by which a test pattern may be created. The process begins at block 502 where a center point for each wafer is established. Of course, the center point could be any location and serves as the base point for determining all other sample points. Of course, in some embodiments, each point could be determined based by knowing only the location of a prior point. Preferably, the center point is close to the center of the wafer to help achieve a uniform distribution of points across the surface of the wafer.

The process then proceeds to block 504 where the remainder of the sample point locations are determined. In some embodiments, this may be accomplished by solving the equations above for each value of n. Of course, other equations may be used as long as the radial density of the sample points increases as the distance from the center point increases and the angular displacement is constant between sample points.

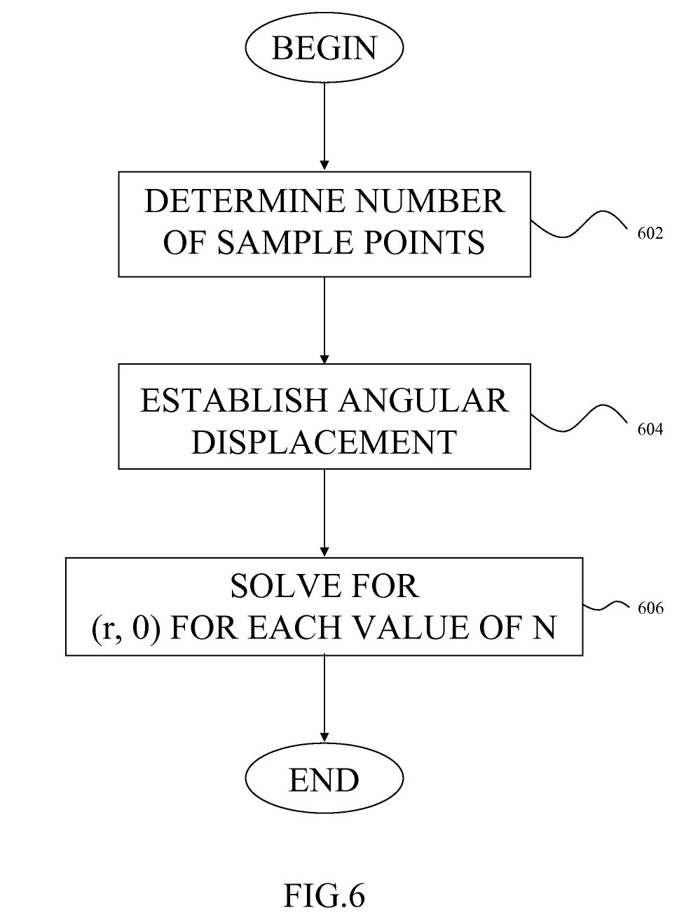

FIG. 6 shows a more detailed flow chart by which the coordinates for test pattern may be generated. The process begins at block 602 where the number of sample points is determined and, consequently N is set. In one embodiment, the number of sample points is 121 and N is, therefore, 60. In addition, as described above, the domain of an index variable n may also be set to −N to N.

At block 604 the angular displacement between each sample point is set. In one embodiment, the angular displacement in 33(π/2).

At block 606 the co-ordinates for each sample point (including (0, 0); the center point) are created. In one embodiment, this may be accomplished by solving for r and θ for each value of n based on the equations above.

As is well known in the art, annealing machines may include test portions that are capable of receiving information related to the process performance at multiple points on the surface of a wafer (such as a plurality of sheet resistance values) and reconfiguring its operation to, hopefully, achieve more uniform process performance (such as sheet resistance) across the surface of a wafer. Advantageously, providing information based on samples taken according to the present invention may give a more realistic representation of the actual conditions on the surface of the wafer.

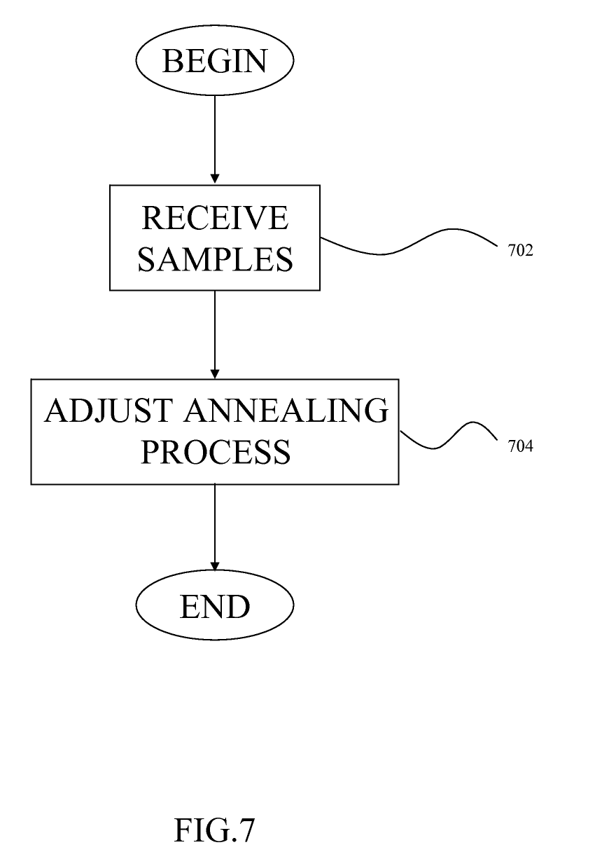

FIG. 7 shows a method for testing a test wafer to determine the effectiveness of an annealing process. The process begins at block 702 where an annealing machine receives a plurality of sheet resistance samples taken from a surface of the test wafer. In one embodiment, the samples may be taken at successive sample locations on the surface of the wafer where the radial displacement of each successive sample location from its predecessor decreases in radial distance as the distance from a center point of the test wafer increases and the angular displacement between each successive sample location is constant. The process continues in block 704 where the annealing machine may adjust the annealing process based on the plurality of sheet resistance samples. In some embodiments, these adjustments may include altering the intensity of one or more lamps in the annealing chamber of the annealing machine. In some embodiments, the adjusting may include adjusting the location where a wafer is deposited in the annealing chamber.

As described above, embodiments can include computer-implemented processes and apparatuses for practicing those processes. In some exemplary embodiments, the invention is embodied in computer program code executed by one or more network elements. Embodiments include computer program code containing instructions embodied in tangible media, such as floppy diskettes, CD-ROMs, hard drives, or any other computer-readable storage medium, wherein, when the computer program code is loaded into and executed by a computer, the computer becomes an apparatus for practicing the invention. Embodiments include computer program code, for example, whether stored in a storage medium, loaded into and/or executed by a computer, or transmitted over some transmission medium, such as over electrical wiring or cabling, through fiber optics, or via electromagnetic radiation, wherein, when the computer program code is loaded into and executed by a computer, the computer becomes an apparatus for practicing the invention. When implemented on a general-purpose microprocessor, the computer program code segments configure the microprocessor to create specific logic circuits.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. A method for creating a testing pattern for sampling the sheet resistance of a test wafer for tuning an annealing process, the method comprising:
establishing a center point for the wafer; and
determining a plurality of sample points having a radial displacement from the center point of the wafer and an angular displacement, the density of radial displacements decreasing as the distance from the center point increases and the density of angular displacements being constant around the wafer.

2. The method of claim 1, wherein the density of the radial displacement of successive sample points increases as the radial displacement increases.

3. The method of claim 2, wherein the density of the radial displacement of successive sample points increases quadratically as the radial displacement increases.

4. The method of claim 1, further comprising establishing a first value N which is related to a number of sample points for the testing pattern.

5. The method of claim 4, further comprising establishing a maximum radius R for the testing pattern.

6. The method of claim 5, wherein the number of sample points is equal to 2N+1.

7. The method of claim 6, further comprising establishing a domain of an index value n to vary from −N to N.

8. The method of claim 7, wherein determining the radial displacement r for each successive value of n equals R times the square root of the quotient of the absolute value of n divided by N.

9. The method of claim 7, further comprising establishing an angular displacement k between each sample point.

10. The method of claim 9, wherein determining angular coordinates for each sample points includes adding k/N to a prior point.

11. The method of claim 7, wherein, for each value of n less than zero, the angular displacement is equal to π−nk/N.

12. The method of claim 7, wherein, for each value of n greater than or equal to zero, the angular displacement is equal to nk/N.

13. A method for testing a test wafer to determine the effectiveness of an annealing process comprising:
receiving a plurality of sheet resistance samples taken from a surface of the test wafer, the samples being taken at successive sample locations on the surface of wafer where a radial displacement of each successive sample location decreases in radial distance from one another as the distance from a center point of the test wafer increases and the angular displacement between each successive sample location is constant; and
adjusting the annealing process based on the plurality of sheet resistance samples.
